(19) United States
(12) Patent Application Publication
(10) Pub. No.: US 2026/0052630 A1
(43) Pub. Date: Feb. 19, 2026

(54) TWO-LEVEL PRINTED CIRCUIT BOARDS IN A CARD-BASED COMPUTING DEVICE

(71) Applicant: NVIDIA CORPORATION, Santa Clara, CA (US)

(72) Inventors: Jaekyu JUNG, Los Gatos, CA (US); Shahin AMIRI, Santa Clara, CA (US); Malcolm GUTENBURG, San Francisco, CA (US); Yunseok KIM, Pleasanton, CA (US); Boris LANDWEHR, Los Gatos, CA (US); Siarhei MURAUYOU, Los Gatos, CA (US); Jungho NA, Milpitas, CA (US); Xiang SUN, Los Gatos, CA (US)

(21) Appl. No.: 18/806,431

(22) Filed: Aug. 15, 2024

(51) Int. Cl. H05K 1/14; G06F 1/18; G06F 1/20; H05K 1/02

(52) U.S. Cl. CPC H05K 1/141; G06F 1/184; G06F 1/20; H05K 1/0203; H05K 2201/042; H05K 2201/064; H05K 2201/066

(57) ABSTRACT

According to various embodiments, a processing subsystem includes: a first printed circuit board (PCB) that includes an edge connector that is oriented perpendicular to a first coordinate axis and is located at a first level on the first coordinate axis, and a second PCB that is perpendicular to the first coordinate axis and located at a second level on the first coordinate axis, wherein the second level is different from the first level, and the second PCB has a topside on which a processor is mounted.

### BACKGROUND

### Field of the Various Embodiments

The various embodiments relate generally to computer systems and thermal solution technology and, more specifically, to two-level printed circuit boards in a card-based computing device.

### Description of the Related Art

In modern computing devices, central processing units (CPUs), graphics processing units (GPUs), and other integrated circuits (ICs) require increasing amounts of power and thus generate increasing quantities of heat during operation. This heat needs to be removed from a computing device in order for the integrated circuits and computing device, as a whole, to operate effectively. For example, a single high-power chip, such as a CPU or GPU, can generate hundreds of watts of heat during operation, and, if this heat is not removed from the computing device, the temperature of the chip can increase to a point where the chip can be permanently damaged. To prevent thermal damage during operation, in addition to implementing conventional cooling systems, many computing devices implement clock-speed throttling when the operating temperature of a given processor exceeds a certain threshold. Accordingly, in these types of computing devices, the processing speed and performance of the high-power chip is constrained by how effectively heat is removed from the chip.

In an attempt to avoid clock-speed throttling and the performance constraints associated with clock-speed throttling other cooling solutions have been implemented in computing devices. One effective technique for removing heat from a chip during operation is increasing the airflow around the chip and within the computing device. However, for many card-based processing subsystems, such as a graphics card that includes a GPU and/or other high-power chip disposed on a printed circuit board (PCB), efficient removal of heat generated by the chip using increased airflow can be hampered by the relatively large size of the PCB, which can act as an obstruction to the airflow. More specifically, graphics cards and other card-based processing subsystems can be installed within a computing device via one of the peripheral component interconnect express (PCIe) slots located on the motherboard of the computing device. The various electronic components of a graphics card, including the GPU and/or other high-power chip, are mounted on the PCB of the graphics card according to PCIe specifications. The PCIe specifications include a limit on the height of the components that can be mounted on the backside of the PCB, which results in a large majority of the electronic components being mounted on the topside of the PCB. In this regard, the GPU and the other relatively taller electronic components, such as the power components, are typically mounted on the topside of the PCB, while only a few relatively shorter electronic components, such as capacitors, are typically mounted on the backside of the PCB. Because most of the electronic components are placed on only one side of the PCB (the topside) to satisfy PCIe specifications, the size of the surface area of the PCB of a conventional graphics card cannot be readily reduced in a way that enhances overall airflow and improves overall heat removal during operation.

As the foregoing illustrates, what is needed in the art are more effective ways to remove heat from card-based processing subsystems during operation.

### SUMMARY

According to various embodiments, a processing subsystem includes: a first printed circuit board (PCB) that includes an edge connector that is oriented perpendicular to a first coordinate axis and is located at a first level on the first coordinate axis, and a second PCB that is perpendicular to the first coordinate axis and located at a second level on the first coordinate axis, wherein the second level is different from the first level, and the second PCB has a topside on which a processor is mounted.

At least one technical advantage of the disclosed two-level PCB design relative to the prior art is that the disclosed design enables the surface area size of the main PCB of a processing subsystem, such as a graphics card, to be substantially reduced relative to the size of the PCB in a conventional processing subsystem. In particular, the two-level PCB design allows relatively taller electronic components to be mounted on the backside of the main PCB, thereby providing a more even distribution of electronic components across the topside and the backside the main PCB relative to the PCB in a conventional processing subsystem. The more even distribution of electronic components across both sides of the main PCB allows the surface area size of the main PCB to be reduced. Consequently, greater overall airflow can be achieved throughout a processing subsystem that incorporates the two-level PCB design by enhancing airflow through a heatsink/exchanger due to the reduced blockage by the PCB and/or enhancing airflow across the backside and topside of the main PCB and the processor and power components mounted thereon. As a result, overall heat removal from the processing subsystem during operation can be improved, which can reduce the temperature of the processor and other mounted electronic components and improve the overall computing performance of the processor and processing subsystem relative to what can be achieved using prior art designs. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a computer system configured to implement one or more aspects of the various embodiments;

FIG. 2 is another illustration of the computer system of FIG. 1, according to various embodiments;

FIG. 3 is an illustration of a conventional card-based processing subsystem that includes multiple fans, according to the prior art;

FIG. 4 is an illustration of a two-level PCB card-based processing subsystem that includes multiple fans, according to various embodiments;

FIG. 5 is an illustration of a side-view of the two-level PCB card-based processing subsystem of FIG. 4, according to various embodiments;

FIG. 6 is an illustration of a perspective side-view of the two-level card-based processing subsystem of FIG. 4, according to various embodiments;

FIG. 7 is an illustration of a conventional card-based processing subsystem that includes a heat sink, according to the prior art;

FIG. 8 is an illustration of a two-level PCB card-based processing subsystem that includes a heat sink, according to various embodiments; and

FIG. 9 is an illustration of a two-level PCB card-based processing subsystem that includes multiple fans and heat sinks, according to various embodiments.

For clarity, identical reference numbers have been used, where applicable, to designate identical elements that are common between figures. It is contemplated that features of one embodiment may be incorporated in other embodiments without further recitation.

### DETAILED DESCRIPTION

In the following description, numerous specific details are set forth to provide a more thorough understanding of the various embodiments. However, it will be apparent to one of skilled in the art that the inventive concepts may be practiced without one or more of these specific details.

### System Overview

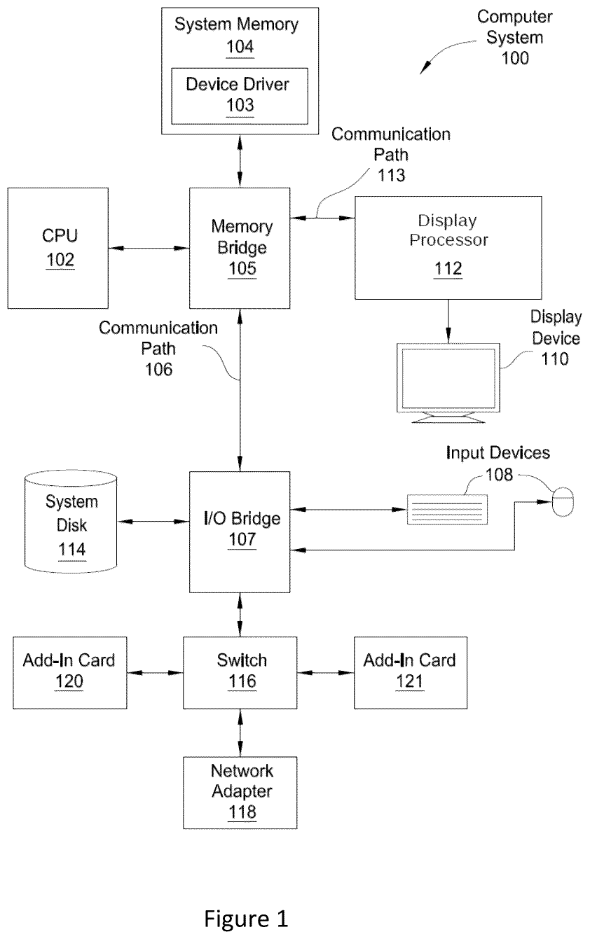

FIG. 1 is a conceptual illustration of a computer system 100 configured to implement one or more aspects of the various embodiments. As shown, system 100 includes a central processing unit (CPU) 102 and a system memory 104 communicating via a bus path that may include a memory bridge 105. CPU 102 includes one or more processing cores, and, in operation, CPU 102 is the master processor of system 100, controlling and coordinating operations of other system components. System memory 104 stores software applications and data for use by CPU 102. CPU 102 runs software applications and optionally an operating system. Memory bridge 105, which may be, e.g., a Northbridge chip, is connected via a bus or other communication path (e.g., a HyperTransport link) to an I/O (input/output) bridge 107. I/O bridge 107, which may be, e.g., a Southbridge chip, receives user input from one or more user input devices 108 (e.g., keyboard, mouse, joystick, digitizer tablets, touch pads, touch screens, still or video cameras, motion sensors, and/or microphones) and forwards the input to CPU 102 via memory bridge 105.

A display processor 112 is coupled to memory bridge 105 via a bus or other communication path (e.g., a PCI Express, Accelerated Graphics Port, or HyperTransport link). In one embodiment, display processor 112 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 104.

Display processor 112 periodically delivers pixels to a display device 110 (e.g., a screen or conventional CRT, plasma, OLED, SED or LCD based monitor or television). Additionally, display processor 112 may output pixels to film recorders adapted to reproduce computer generated images on photographic film. Display processor 112 can provide display device 110 with an analog or digital signal. In various embodiments, a graphical user interface is displayed to one or more users via display device 110, and the one or more users can input data into and receive visual output from the graphical user interface.

A system disk 114 is also connected to I/O bridge 107 and may be configured to store content and applications and data for use by CPU 102 and display processor 112. System disk 114 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 116 provides connections between I/O bridge 107 and other components such as a network adapter 118 and various add-in cards 120 and 121. Network adapter 118 allows system 100 to communicate with other systems via an electronic communications network, and may include wired or wireless communication over local area networks and wide area networks such as the Internet.

Other components (not shown), including USB or other port connections, film recording devices, and the like, may also be connected to I/O bridge 107. For example, an audio processor may be used to generate analog or digital audio output from instructions and/or data provided by CPU 102, system memory 104, or system disk 114. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 112 is configured as a processing subsystem that incorporates circuitry optimized for graphics and video processing, including, for example, video output circuitry, and constitutes a graphics processing unit (GPU). In another embodiment, display processor 112 is configured as a processing subsystem that incorporates circuitry optimized for general purpose processing. In yet another embodiment, display processor 112 may be integrated with one or more other system elements, such as the memory bridge 105, CPU 102, and I/O bridge 107 to form a system on chip (SoC). In still further embodiments, display processor 112 is omitted and software executed by CPU 102 performs the functions of display processor 112.

Pixel data can be provided to display processor 112 directly from CPU 102. In some embodiments, instructions and/or data representing a scene are provided to a render farm or a set of server computers, each similar to system 100, via network adapter 118 or system disk 114. The render farm generates one or more rendered images of the scene using the provided instructions and/or data. These rendered images may be stored on computer-readable media in a digital format and optionally returned to system 100 for display. Similarly, stereo image pairs processed by display processor 112 may be output to other systems for display, stored in system disk 114, or stored on computer-readable media in a digital format.

Alternatively, CPU 102 provides display processor 112 with data and/or instructions defining the desired output images, from which display processor 112 generates the pixel data of one or more output images, including characterizing and/or adjusting the offset between stereo image pairs. The data and/or instructions defining the desired output images can be stored in system memory 104 or graphics memory within display processor 112. In an embodiment, display processor 112 includes 3D rendering capabilities for generating pixel data for output images from instructions and data defining the geometry, lighting shading, texturing, motion, and/or camera parameters for a scene. Display processor 112 can further include one or more programmable execution units capable of executing shader programs, tone mapping programs, and the like.

Further, in other embodiments, CPU 102 or display processor 112 may be replaced with or supplemented by any technically feasible form of processor (processing device) configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 102, display processor 112, or one or more other processing devices or any combination of these different processors.

CPU 102, render farm, and/or display processor 112 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

It will be appreciated that the system shown herein is illustrative and that variations and modifications are possible. The connection topology, including the number and arrangement of bridges, may be modified as desired. For instance, in some embodiments, system memory 104 is connected to CPU 102 directly rather than through a bridge, and other devices communicate with system memory 104 via memory bridge 105 and CPU 102. In other alternative topologies display processor 112 is connected to I/O bridge 107 or directly to CPU 102, rather than to memory bridge 105. In still other embodiments, I/O bridge 107 and memory bridge 105 might be integrated into a single chip. The particular components shown herein are optional; for instance, any number of add-in cards or peripheral devices might be supported. In some embodiments, switch 116 is eliminated, and network adapter 118 and add-in cards 120, 121 connect directly to I/O bridge 107.

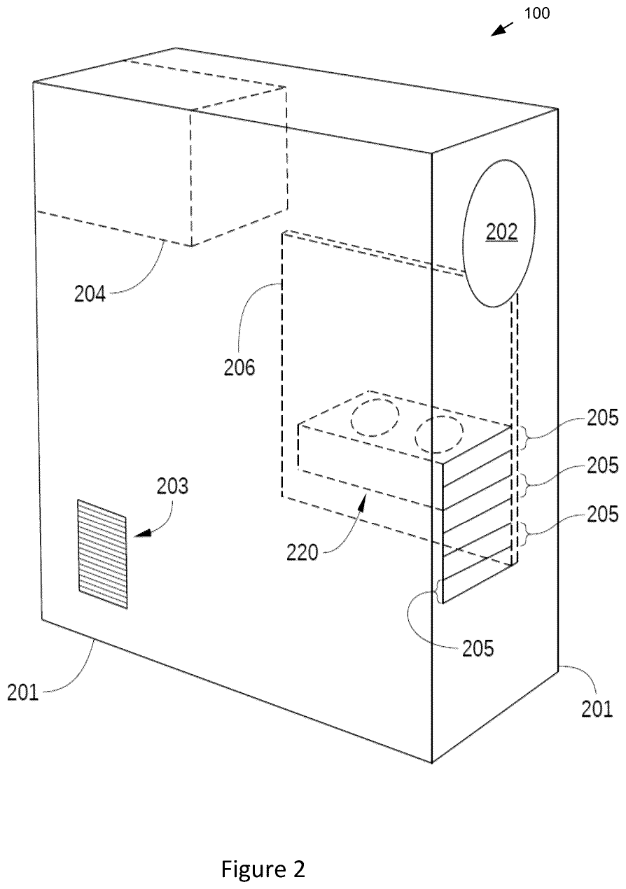

FIG. 2 is another illustration of the computer system 100 of FIG. 1, according to various embodiments. As shown, computer system 100 includes a chassis 201 (also referred to as a “case” or “housing”) with one or more system cooling fans 202 mounted thereon and one or more cooling inlets 203 formed therein. Cooling fans 202 are configured to draw cooling air into chassis 201, for example via cooling inlets 203, to remove heat generated by various electronic components of computer system 100. Computer system 100 further includes a power supply 204 mounted within chassis 201, a plurality of chassis expansion slots 205 that are typically located on a rear surface of chassis 201, and a motherboard 206 disposed within chassis 201.

Computer system 100 further includes various external connections (omitted for clarity) mounted on a rear and/or front surface of chassis 201, such as a power connection, Universal Serial Bus (USB) connections, an audio input jack, an audio output jack, one or more video output connections, and/or other connections. In some embodiments, one or more of such external connections are associated with motherboard 206 or an expansion card that is coupled to motherboard 206 and installed in a chassis expansion slot 205, such as a card-based processing subsystem 220.

In the embodiment illustrated in FIG. 2, motherboard 206 is configured with a central processing unit (CPU) and one or more card edge connectors, such as peripheral component interconnect express (PCIe) slots, that are each positioned to correspond to a different chassis expansion slot 205. For clarity, the CPU and card edge connectors of motherboard 206 are omitted in FIG. 2. Generally, computer system 100 is configured with one or more expansion cards or other card-based processing subsystems that are each mounted in a different chassis expansion slot 205 and communicatively coupled to motherboard 206 via a corresponding edge connector. Examples of such card-based processing subsystems include card-based processing subsystems 220, such as wireless adapters, sound cards, graphics cards, network adapter 118, add-in cards 120, 121, or display processor 112 of FIG. 1, and/or the like. In the embodiment illustrated in FIG. 2, a single card-based processing subsystem 220 is coupled to motherboard 206, but in other embodiments, a plurality of card-based processing subsystems 220 may be coupled to motherboard 206.

In some embodiments, computer system 100 further includes one or more peripheral devices (not shown) that are communicatively coupled to motherboard 206 and/or a particular expansion card coupled to motherboard 206. For example, in some embodiments, computer system 100 includes one or more of a keyboard, mouse, joystick, digitizer tablet, touch pad, touch screen, display device, external hard drive, still or video cameras, motion sensors, microphones, and/or the like.

In the embodiment illustrated in FIG. 2, computer system 100 is depicted as a tower-configured desktop computer system. In other embodiments, computer system 100 can have any configuration that can include a card-based processing subsystem, such as a tower server computer system, a blade server computer system, a rack server computer system, a laptop computer, and the like.

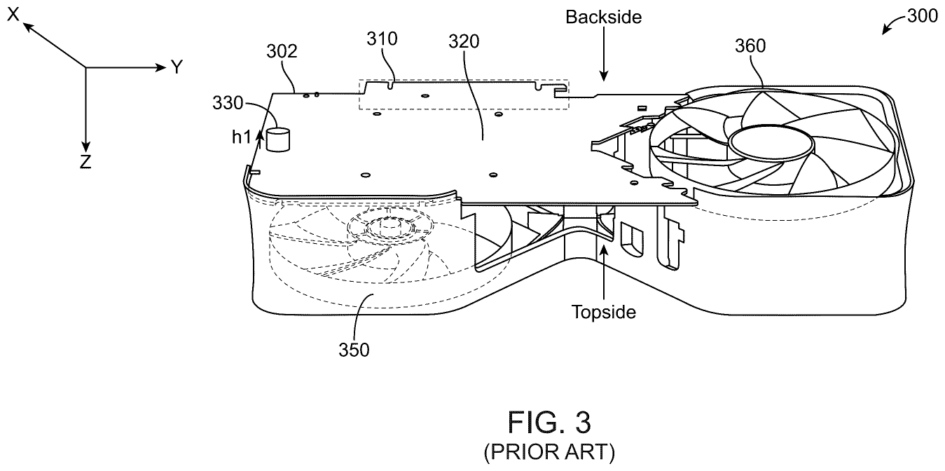

FIG. 3 is an illustration of a conventional card-based processing subsystem 300 that includes multiple fans, according to the prior art. The conventional card-based processing subsystem 300 can be implemented in the computer system 100 shown in FIGS. 1-2. FIG. 3 shows a bottom-side view of the conventional card-based processing subsystem 300. As shown, the processing subsystem 300 includes a single PCB 302, a first fan 350, and a second fan 360.

The single PCB 302 is typically oriented on a single plane that is perpendicular to a first coordinate axis (such as the Z axis). In the example of FIG. 3, for the sake of clarity, the conventional card-based processing subsystem 300 is shown upside down, whereby the first coordinate axis increases in value going from the top to the bottom of FIG. 3. As used herein, the dimension associated with the first coordinate axis is generically referred to as “height,” whereby the “height” of a component or other feature is measured relative to and based on the first coordinate axis. As such, a backside of the single PCB 302 is visible in FIG. 3, whereas a topside of the single PCB 302 is not visible in FIG. 3. The surface area size of the single PCB 302 is defined by the dimensions of the single PCB 302 along a second coordinate axis (such as the Y axis) and a third coordinate axis (such as the X axis). As shown, the surface area size of the single PCB 302 extends from a left side of the first fan 350 to a left side of the second fan 360.

The single PCB 302 includes different sub-portions, including an edge connector 310 (indicated by the dashed box) and a main PCB 320 (comprising a remaining portion of the single PCB 302). The edge connector 310 is configured to couple/connect to a corresponding chassis expansion slot 205 in order to communicatively couple the processing subsystem 300 to the motherboard 206 of the computer system 100. The main PCB 320 includes various components that are mounted on the backside and topside of the main PCB 320. In particular, the processor (such as a GPU or any other type of processing device) is typically mounted on the topside of the main PCB 320. The processing subsystem 300 can comprise a PCIe processing subsystem 300 that is coupled, via the edge connector 310, to a PCIe chassis expansion slot 205 of the motherboard 206 of the computer system 100. Accordingly, the various components that are mounted on the main PCB 320 are required to comply with PCIe specifications/restrictions that include a maximum limit on the height of components that can be mounted on the backside of the single PCB 302 (referred to herein as “backside mounted components”). For example, the maximum height limit on backside components on a standard PCIE can be 2.67 mm. In other embodiments, the maximum height limit on backside components can be another value.

Under the PCIe specifications, the height of a backside mounted component on the single PCB 302 is measured relative to a backside surface of the edge connector 310. Since the single PCB 302 is typically oriented on a single plane that is perpendicular to the first coordinate axis, the entirety of the single PCB 302 is located at a first level on the first coordinate axis. As such, the edge connector 310 and the main PCB 320 will both be located at the same first level on the first coordinate axis. Thus, for purposes of determining compliance with the PCIe specifications, the height of a backside mounted component can be determined based on the backside surface of the main PCB 320. For example, the main PCB 320 can include a first component 330 mounted on the backside of the main PCB 320 having a first height (h1). The first height (h1) can be measured from a bottom of the first component 330 that is mounted on the backside surface of the main PCB 320 (which is at the same first level as the edge connector 310) to a top of the first component 330. The resulting height measurement of each backside mounted component must be less than or equal to the maximum height limit defined by the PCIe specifications.

As a result of the above PCIe specification, relatively taller components, such as power components and the like, are typically mounted on the topside of the main PCB 320. In addition, the processor and memory are also typically mounted on the topside of the main PCB 320. In contrast, only a few shorter components, such as capacitors, can be mounted on the backside of the main PCB 320. As a result, there is an uneven distribution of components across the backside and topside of the main PCB 320, whereby a large majority of components are typically mounted on the topside of the main PCB 320. Consequently, the surface area size of the single PCB 302 of the conventional card-based processing subsystem 300 cannot be significantly reduced to enhance airflow and improve heat removal from the conventional card-based processing subsystem 300.

### Two-Level PCBs in a Processing Subsystem

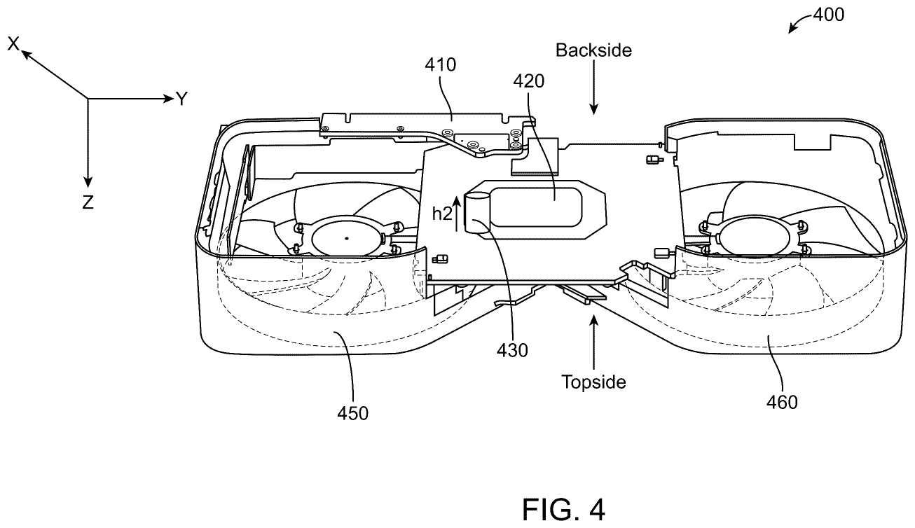

FIG. 4 is an illustration of a two-level PCB card-based processing subsystem 400 that includes multiple fans, according to various embodiments. The card-based processing subsystem 400 can be implemented in the computer system 100 shown in FIGS. 1-2. FIG. 4 shows a bottom-side view of the processing subsystem 400. As shown, the processing subsystem 400 includes a first PCB 410, a second PCB 420, a first fan 450, and a second fan 460.

The first fan 450 and the second fan 460 can be mechanically connected/coupled to the first PCB 410 and/or second PCB 420. The first fan 450 and second fan 460 are oriented to provide airflow and force cooling air (or any other suitable cooling fluid) around the second PCB 420 and through the processing subsystem 400 in an axial direction (a vertical direction through the axes of the fans). In other embodiments, the first fan 450 and second fan 460 can be oriented to provide airflow and force cooling air (or any other suitable cooling fluid) around the second PCB 420 and through the processing subsystem 400 in a centrifugal/radial direction (a horizontal direction).

The first PCB 410 comprises a card edge connector 410 and the second PCB 420 comprises a main PCB 420. The card edge connector 410 is adaptable to be and configured to couple/connect to a corresponding chassis expansion slot 205 of the motherboard 206 of the computer system 100 in order to communicatively couple the processing subsystem 400 to the motherboard 206. The main PCB 420 includes various components that are mounted on the backside and topside of the main PCB 420. The mounted components include various electrical circuit components, including relatively taller components and relatively shorter components. The relatively taller components can include processors (such as a CPU or GPU), some types of power components (such as inductors), special types of capacitors (such as can-type capacitors or conductive polymer aluminum solid capacitors (OS-CON)), and the like. Power components can include inductors, MOSFETs, and the like. The relatively shorter components can include MOSFETs, resistors, generic capacitors, controllers, and the like. Note that while MOSFETs are power components that are relatively shorter components, MOSFETs and inductors are placed adjacent to each other in a typical PCB design. Thus, while MOSFETs could fit onto the backside of a PCB while meeting the maximum height limit on backside components, MOSFETs are typically not mounted onto the backside of the PCB since the inductors would not be able to fit onto the backside of a PCB while meeting the maximum height limit on backside components. Typically, the processor (not shown) is mounted on the topside of the main PCB 420. However, in some embodiments, at least one processor (such as a CPU or GPU) is mounted on the backside of the main PCB 420. In additional embodiments, at least one processor is mounted on the topside of the main PCB 420, and at least one additional processor is mounted on the backside of the main PCB 420.

In the example of FIG. 4, for the sake of clarity, the processing subsystem 400 is shown upside down, whereby a first coordinate axis (such as the Z axis) increases in value going from the top to the bottom of FIG. 4. As such, a backside of the main PCB 420 is visible in FIG. 4, whereas a topside of the main PCB 420 is not visible in FIG. 4. In the example of FIG. 4, the first coordinate axis comprises the Z axis, the second coordinate axis comprises the Y axis, and the third coordinate axis comprises the X axis, which are largely arbitrary and based on an example orientation of the processing subsystem 400 within the computer system 100. In other embodiments, the orientation of the processing subsystem 400 within the computer system 100 is different than in the example of FIG. 4, and the first coordinate axis comprises the X or Y axis, the second coordinate axis comprises the X or Z axis, and the third coordinate axis comprises the Y or Z axis.

The first PCB 410 (edge connector 410) and the second PCB 420 (main PCB 420) comprise separate and different PCBs that are connected by a board-to-board connector (not shown). The first PCB 410 is oriented on a first plane that is perpendicular to the first coordinate axis and located at a first level on the first coordinate axis. The second PCB 420 is oriented on a second plane that is perpendicular to the first coordinate axis and located at a second level on the first coordinate axis. The second level is different from the first level on the first coordinate axis. In terms of relative orientation, the backside of the second PCB 420 faces towards the first PCB 410 and the topside of the second PCB 420 faces away from the first PCB 410. In the example of FIG. 4, whereby the first coordinate axis (such as the Z axis) increases in value going from the top to the bottom of FIG. 4, the second level will have a corresponding second value (such as a second Z value) that is greater than a first value (such as a first Z value) corresponding to the first level. In contrast, if the first coordinate axis (such as the Z axis) decreases in value going from the top to the bottom of FIG. 4, the second level will have a corresponding second value (such as a second Z value) that is less than a first value (such as a first Z value) corresponding to the first level.

The processing subsystem 400 can comprise a PCIe processing subsystem 400 that is coupled, via the edge connector 410, to a PCIe chassis expansion slot 205. Accordingly, the various components that are mounted on the main PCB 420 are required to comply with PCIe specifications/requirements that include a maximum limit on the height of components that can be mounted on the backside of the main PCB 420. Advantageously, the second level of the main PCB 420 enables taller components to be mounted on the backside of the main PCB 420 relative to prior designs, while still satisfying PCIe height limit specification which is based on and references the first level of the edge connector 410. In particular, the maximum height limit of backside mounted components on the main PCB 420 are measured in relation to the surface of the edge connector 410 at the first level on the first coordinate axis under PCIe specifications. By moving the main PCB 420 to a different second level on the first coordinate axis, the actual height of backside mounted components on the main PCB 420 can be increased while still satisfying the PCIe height limit specification which is based on the first level of the edge connector 410. The increase in actual physical height of the backside mounted components achieved by the two-level PCB design of the processing subsystem 400, while still satisfying the PCIe height limit specification, is equal to the absolute difference/delta in height between the first level and the second level along the first coordinate axis (referred to herein as the “level delta”).

For example, the main PCB 420 can include a second component 430 mounted on the backside of the main PCB 420 having a second height (h2). The second height (h2) is measured from a bottom of the second component 430 that is mounted on the backside surface of the main PCB 420 at the second level to a top of the second component 430. The second height (h2) is the “actual height” (actual physical height) of the second component 430. However, the “specification height” of the second component 430 for determining compliance with the PCIe height limit specification is different from the “actual height” of the second component 430. The “specification height” of the second component 430 for determining compliance with the PCIe height limit specification is measured from the backside surface of the edge connector 410 at the first level to the top of the second component 430. In general, the “specification height” of a backside mounted component is less than the “actual height” of the same backside mounted component. As a result, components having taller actual height can now be mounted on the backside relative to prior designs.

Consequently, the two-level PCB design allows relatively taller components to now be mounted on the backside of the main PCB 420, while still meeting PCIe specifications. The level delta between the first level and the second level along the first coordinate axis defines the increase in height of the backside mounted components achieved by the two-level PCB design, while still satisfying the PCIe height limit specification. As a result, there is a more even distribution of components across the backside and topside of the main PCB 420, whereby a greater number of components can be mounted on the backside of the main PCB 420 relative to prior designs. The more even distribution of components across the backside and topside of the main PCB 420 allows the surface area size of the PCB 420 to be reduced relative to prior designs. The surface area size of the main PCB 420 is defined by the dimensions of the main PCB 420 along the second coordinate axis and the third coordinate axis. As shown, the surface area size of the main PCB 420 extends from a right side of the first fan 450 to a left side of the second fan 460. Notably, the surface area size of the main PCB 420 of the two-level PCB design of processing subsystem 400 is significantly smaller than the surface area size of the main PCB 320 of the conventional processing subsystem 300. By reducing the surface area size of the main PCB 420, the airflow in the processing subsystem 400 is increased, thereby improving heat removal and computing performance of the processing subsystem 400.

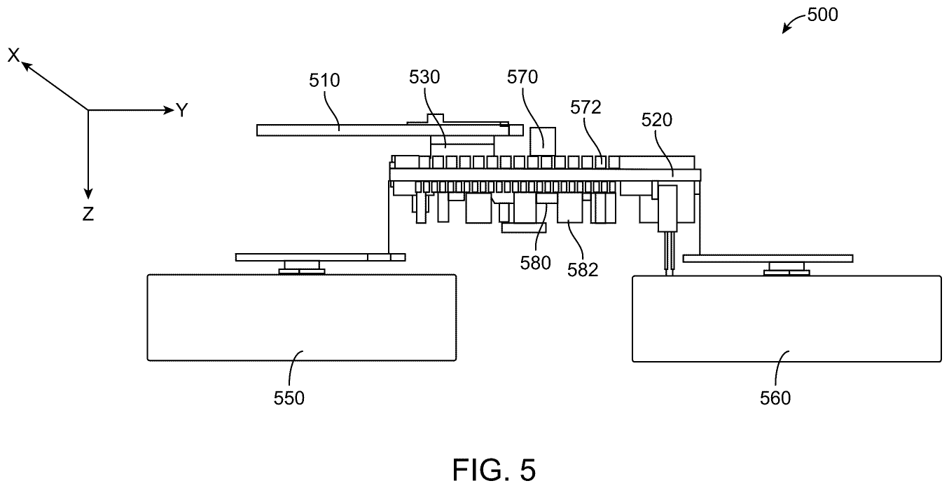

FIG. 5 is an illustration of a side-view of the two-level PCB card-based processing subsystem 500 of FIG. 4, according to various embodiments. The card-based processing subsystem 500 can be implemented in the computer system 100 shown in FIGS. 1-2. As shown, the processing subsystem 500 includes a first PCB 510, a second PCB 520, a board-to-board connector 530, a first fan 550, and a second fan 560. The first PCB 510, second PCB 520, first fan 550, and second fan 560 are discussed in relation to FIG. 4 and are not discussed in detail here.

The first PCB 510 comprises an edge connector 510 and the second PCB 520 comprises a main PCB 520. The board-to-board connector 530 couples the edge connector 510 to the main PCB 520 in order to communicatively connect/couple the edge connector 510 and the main PCB 520. In particular, the board-to-board connector 530 transmits high speed signals and power to and from the edge connector 510 and the main PCB 520. Use of the board-to-board connector 530 allows the edge connector 510 and the main PCB 520 to be separated into two different PCBs that are located on two different planes at two different levels along the first coordinate axis. Notably, the height of the board-to-board connector 530 along the first coordinate axis (such as the Z axis) can correspond to and be used to define the level delta between the first level of the first PCB 510 (edge connector 510) and the second level of the second PCB 520 (main PCB 520) along the first coordinate axis.

As shown, the main PCB 520 includes a plurality of topside mounted components, such as a first topside mounted component 580 and a second topside mounted component 582. The topside mounted components can include relatively taller components, such as power components. The first topside mounted component 580 can comprise a processor, such as a GPU or any other type of processing device. The main PCB 520 also includes a plurality of backside mounted components, such as a first backside mounted component 570 and a second backside mounted component 572. The backside mounted components can also include relatively taller components, such as power components.

In conventional designs, the power-intensive processor and all power components are typically mounted on the topside of the main PCB, which causes a concentration of power located around the processor, which further increases the heat around the processor. The concentrated zone of power around the processor on the topside of the main PCB increases the temperature of the processor and makes it more difficult to remove heat around the processor. As an additional technical advantage of the disclosed two-level PCB design, some of the power components can now be mounted on the backside of the main PCB. As a result, the concentration of power on the topside of the main PCB is reduced near the processor, and thus amount of heat near the processor is automatically reduced, which further advances the computing performance of the processing subsystem.

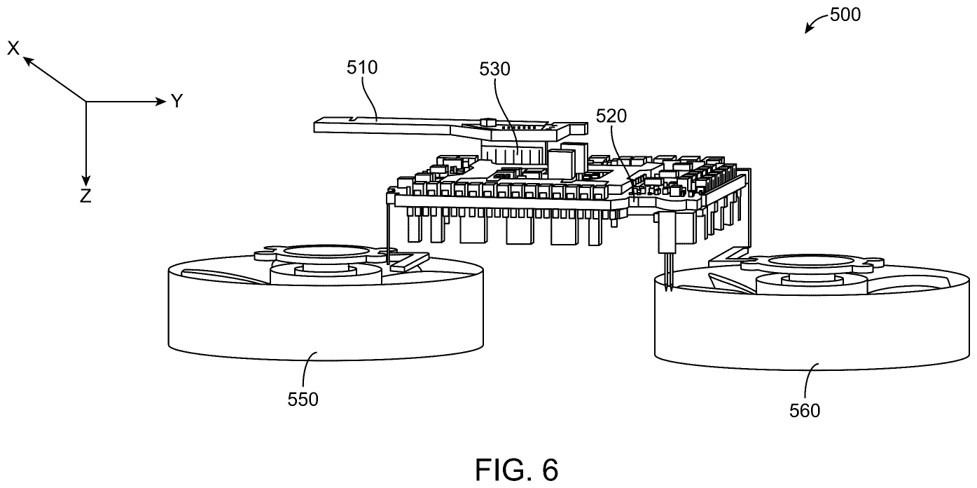

FIG. 6 is an illustration of a perspective side-view of the two-level card-based processing subsystem of FIG. 4, according to various embodiments. As shown, the processing subsystem 500 includes a first PCB 510, a second PCB 520, a board-to-board connector 530, a first fan 550, and a second fan 560.

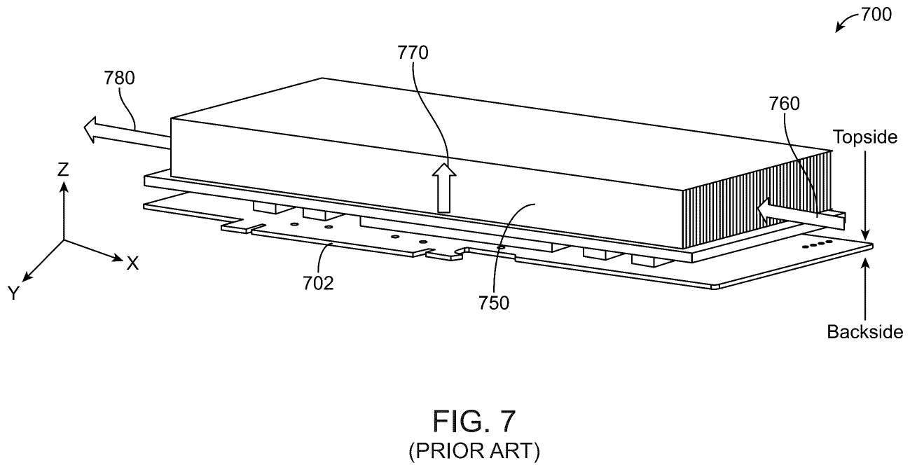

FIG. 7 is an illustration of a conventional card-based processing subsystem that includes a heat sink, according to the prior art. The conventional card-based processing subsystem 700 can be implemented in the computer system 100 shown in FIGS. 1-2. FIG. 7 shows a perspective side-view of the conventional card-based processing subsystem 700. As shown, the processing subsystem 700 includes a single PCB 702 and a topside heat sink/exchanger 750 that includes a plurality of cooling fins. The single PCB 702 has a topside and a backside, and includes an edge connector and a main PCB. In the example of FIG. 7, the conventional card-based processing subsystem 700 is right sight up, whereby the first coordinate axis increases in value going from the bottom to the top of FIG. 7. As such, a topside of the single PCB 702 is visible in FIG. 7, whereas a backside of the single PCB 702 is not visible in FIG. 7.

As shown, an input airflow 760 enters from the right side of the topside heat sink 750, and an output airflow 780 exits from the left side of the topside heat sink 750, which thereby provides passive cooling to the single PCB 702. The source of the input airflow 760 can be, for example, a server fan or other external airflow source. The direction of the input airflow 760 is exemplary only, and in other embodiments, the input airflow 760 from another direction. A topside airflow 770 exits the topside heat sink 750 from the topside of the single PCB 702 to remove heat from the topside of the single PCB 702. Thus, the conventional processing subsystem 700 can provide passive cooling to the topside of the single PCB 702 via the topside heat sink 750. However, providing passive cooling to the backside of the single PCB 702, including the backside of the main PCB, is difficult as there is little room for airflow on the backside of the single PCB 702.

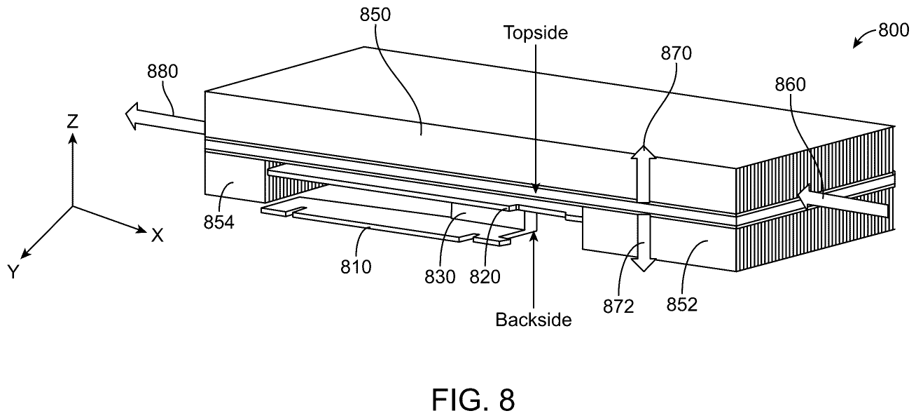

FIG. 8 is an illustration of a two-level PCB card-based processing subsystem 800 that includes a heat sink, according to various embodiments. The processing subsystem 800 can be implemented in the computer system 100 shown in FIGS. 1-2. FIG. 8 shows a perspective side-view of the processing subsystem 800.

As shown, the processing subsystem 800 includes a first PCB 810 (edge connector 810), a second PCB 820 (main PCB 820), a board-to-board connector 830, a topside heat sink/exchanger 850 that includes a plurality of cooling fins, a first backside heat sink/exchanger 852 that includes a plurality of cooling fins, and a second backside heat sink/exchanger 854 that includes a plurality of cooling fins. The topside heat sink 850, the first backside heat sink 852, and the second backside heat sink 854 are each directly or indirectly coupled (thermally and/or mechanically) to the main PCB 820 to provide passive cooling for the main PCB 820. The main PCB 820 has a topside and a backside.

In the example of FIG. 8, the processing subsystem 800 is right-side up, whereby the first coordinate axis increases in value going from the bottom to the top of FIG. 8. As such, a topside of the main PCB 820 is visible in FIG. 8, whereas a backside of the main PCB 820 is not visible in FIG. 8. In terms of relative orientation, the backside of the second PCB 820 faces towards the first PCB 810 and the board-to-board connector 830 and the topside of the second PCB 820 faces away from the first PCB 410 and the board-to-board connector 830, while the board-to-board connector 830 is placed in-between the first PCB 410 and the second PCB 820 along the first coordinate axis.

As shown, an input airflow 860 enters from the right side of the topside heat sink 850 and the first backside heat sink 852, and an output airflow 880 exits from the left side of the topside heat sink 850 and the second backside heat sink 854, which thereby provides passive cooling to the topside and backside of the main PCB 820. The source of the input airflow 860 can be, for example, a server fan or other external airflow source. The direction of the input airflow 860 is exemplary only, and in other embodiments, the input airflow 860 from another direction. In addition, a topside airflow 870 exits the topside heat sink 850 from the topside of the main PCB 820 to remove heat from the topside of the main PCB 820. Thus, the processing subsystem 800 can provide further passive cooling to the topside of the main PCB 820 via the topside heat sink 850. In addition, a backside airflow 872 exits the first backside heat sink 852 and the second backside heat sink 854 from the backside of the main PCB 820 to remove heat from the backside of the main PCB 820. Thus, the processing subsystem 800 can provide further passive cooling to the backside of the main PCB 820 via the first backside heat sink 852 and the second backside heat sink 854.

As shown, due to the gap between the first PCB 810 (edge connector 810) and the second PCB 820 (main PCB 820) created by the two-level PCB design architecture, an airflow can now be provided to the backside of the main PCB 820 to enable passive cooling of the various backside mounted components. In addition, the elevated second level of the main PCB 820 (along the first coordinate axis) created by the two-level PCB design architecture allows additional heat sinks to be added to the processing subsystem 800. For example, the first backside heat sink 852 can be coupled (thermally and/or mechanically) to the right-bottom side of the topside heat sink 850 and/or coupled (thermally and/or mechanically) to the right side of the main PCB 820. As another example, the second backside heat sink 854 can be coupled (thermally and/or mechanically) to the left-bottom side of the topside heat sink 850 and/or coupled (thermally and/or mechanically) to the left side of the main PCB 820.

Also due to the elevated second level of the main PCB 820 (along the first coordinate axis), the first backside heat sink 852 and the second backside heat sink 854 can each connect to the bottom side of the topside heat sink 850 and extend towards and extend below the second level of the main PCB 820 (along the first coordinate axis). In some embodiments, the first backside heat sink 852 and the second backside heat sink 854 can each extend towards and reach the first level of the edge connector 810 (along the first coordinate axis). In these embodiments, the processing subsystem 800 is enclosed on the topside by the topside heat sink 850, enclosed on the right side by the first backside heat sink 852, and enclosed on the left side by the second backside heat sink 854.

In some embodiments, the topside heat sink 850 is directly coupled (thermally and/or mechanically) to the processor (such as a GPU) that is mounted on the topside of the main PCB 820, to provide further passive cooling to the processor. In these embodiments, the backside of the main PCB 820 includes all relatively tall components so that only relatively shorter components are mounted on the topside of the main PCB 820. For example, the backside of the main PCB 820 can include all components that are taller in height (along the first coordinate axis) than the processor, whereby the processor is then the tallest component mounted on the topside of the main PCB 820, thereby allowing the topside heat sink 850 to be directly coupled (thermally and/or mechanically) to the processor. In prior designs, the taller components mounted on the topside of the main PCB can prevent such direct coupling of the topside heat sink to the processor.

In the above embodiments relating to FIGS. 4-6, the two-level PCB processing subsystem 400 includes a thermal solution comprising one or more axial fans and/or radial fans. However, in other embodiments, the processing subsystem 400 can further include at least one passive thermal solution, such as a heat sink with fins, that is coupled (thermally and/or mechanically) to the one or more fans and/or the main PCB. In the above embodiments relating to FIG. 8, the two-level PCB processing subsystem 800 includes a thermal solution comprising at least one heat sink/exchanger that includes a plurality of cooling fins. However, in other embodiments, each heat sink/exchanger can be replaced in the processing subsystem 800 by another type of passive thermal solution. In additional embodiments, each heat sink/exchanger can include a vapor chamber and heat pipes that employ evaporative cooling to transfer heat from the main PCB to the cooling fins. In further embodiments, the processing subsystem 800 can further include at least one fan (axial or radial) that is coupled (thermally and/or mechanically) to the at least one heat sink and/or the main PCB. For example, in some embodiments, an inlet fan (axial or radial) can be coupled to the right side of the topside heat sink 850 and/or the first backside heat sink 852 to increase the input airflow 860.

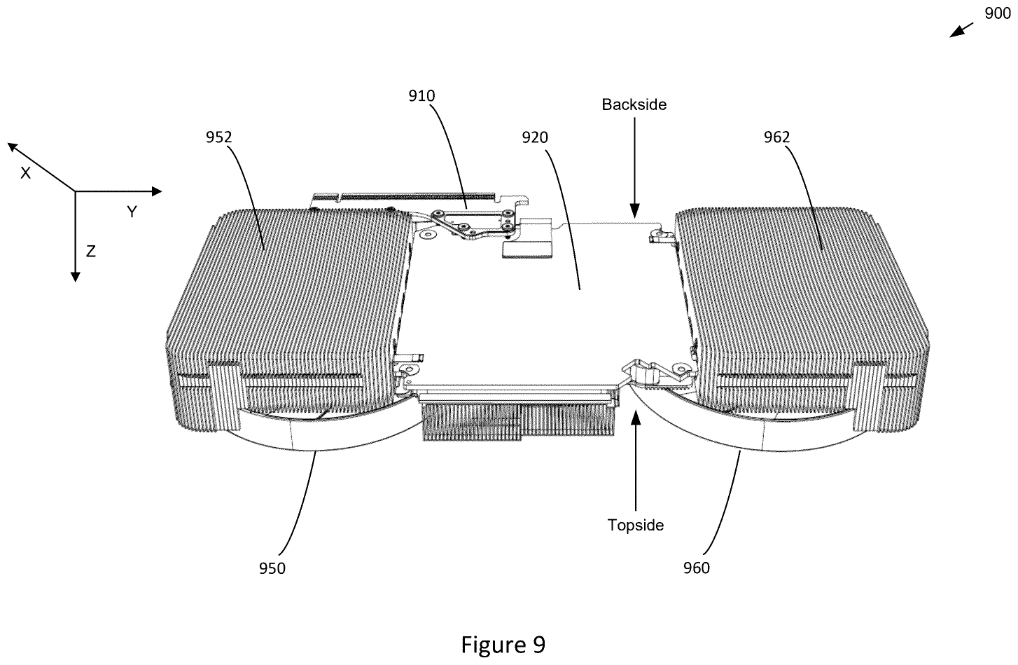

For example, FIG. 9 is an illustration of a two-level PCB card-based processing subsystem 900 that includes multiple fans and heat sinks, according to various embodiments. The processing subsystem 900 can be implemented in the computer system 100 shown in FIGS. 1-2. As shown, the processing subsystem 900 includes a first PCB 910, a second PCB 920, a first fan 950, and a second fan 960. The first PCB 910, second PCB 920, first fan 950, and second fan 960 are discussed in relation to FIG. 4 and are not discussed in detail here. The processing subsystem 900 also includes at least one heat sink/exchanger, such as a first heat sink/exchanger 952 that includes a plurality of cooling fins, and/or a second heat sink/exchanger 962 that includes a plurality of cooling fins. The first heat sink/exchanger 952 can be directly or indirectly coupled (thermally and/or mechanically) to the second PCB 920 and/or the first fan 950. The second heat sink/exchanger 962 can be directly or indirectly coupled (thermally and/or mechanically) to the second PCB 920 and/or the second fan 960.

In sum, a processing subsystem, such as a PCIe graphics card, includes a two-level PCB design architecture comprising a first PCB (an edge connector) and a second PCB (main PCB). The first PCB (edge connector) is oriented on a first plane that is perpendicular to a first coordinate axis and is located at a first level on the first coordinate axis. The second PCB (main PCB) includes various components mounted thereon, including a processor such as a GPU. The second PCB is oriented on a second plane that is perpendicular to the first coordinate axis and is located at a second level on the first coordinate axis. The second level is different from the first level on the first coordinate axis. The processing subsystem also includes a board-to-board connector that communicatively couples/connects the first PCB (edge connector) and the second PCB (main PCB).

The PCIe specifications define a maximum height of components that can be mounted on the backside of the main PCB, whereby the height of the components is measured relative to the first level of the edge connector on the first coordinate axis. In prior designs, the main PCB is located at the same first level of the edge connector on the first coordinate axis, resulting in only relatively shorter components being mounted on the backside of the main PCB due to the PCIe specifications. However, in the disclosed two-level PCB design architecture, the main PCB is located at a second level on the first coordinate axis that is different from the first level of the edge connector on the first coordinate axis, which allows taller components to be mounted on the backside of the main PCB relative to prior approaches, while still meeting/satisfying the PCIe specifications.

In alternative embodiments, the processing subsystem includes a multi-level PCB design architecture comprising three or more different PCB levels. For example, the multi-level PCB design architecture can include a first edge connector, a first main PCB, a first board-to-board connector that communicatively couples/connects the first edge connector and the first main PCB, a second main PCB, and a second board-to-board connector that communicatively couples/connects the first edge connector and the second main PCB. The first edge connector is oriented on a first plane that is perpendicular to a first coordinate axis and is located at a first level on the first coordinate axis, the first main PCB is oriented on a second plane that is perpendicular to the first coordinate axis and is located at a second level on the first coordinate axis, and the second main PCB is oriented on a third plane that is perpendicular to the first coordinate axis and is located at a third level on the first coordinate axis. The first level, second level, and third level are each different levels on the first coordinate axis. In other embodiments, the multi-level PCB design architecture can be implemented in a different manner.

At least one technical advantage of the disclosed two-level PCB design relative to the prior art is that the disclosed design enables the surface area size of the main PCB of a processing subsystem, such as a graphics card, to be substantially reduced relative to the size of the PCB in a conventional processing subsystem. In particular, the two-level PCB design allows relatively taller electronic components to be mounted on the backside of the main PCB, thereby providing a more even distribution of electronic components across the topside and the backside the main PCB relative to the PCB in a conventional processing subsystem. The more even distribution of electronic components across both sides of the main PCB allows the surface area size of the main PCB to be reduced. Consequently, greater overall airflow can be achieved throughout a processing subsystem that incorporates the two-level PCB design by enhancing airflow through a heatsink/exchanger due to the reduced blockage by the PCB and/or enhancing airflow across the backside and topside of the main PCB and the processor and power components mounted thereon. As a result, overall heat removal from the processing subsystem during operation can be improved, which can reduce the temperature of the processor and other mounted electronic components and improve the overall computing performance of the processor and processing subsystem relative to what can be achieved using prior art designs. These technical advantages provide one or more technological advancements over prior art approaches.

Aspects of the subject matter described herein are set out in the following numbered clauses.

1. In some embodiments, a processing subsystem comprises a first printed circuit board (PCB) that includes an edge connector that is oriented perpendicular to a first coordinate axis and is located at a first level on the first coordinate axis, and a second PCB that is perpendicular to the first coordinate axis and located at a second level on the first coordinate axis, wherein the second level is different from the first level, and the second PCB has a topside on which a processor is mounted.

2. The processing subsystem of clause 1, wherein the second PCB has a backside that faces towards the first PCB, and wherein the topside of the second PCB faces away from the first PCB.

3. The processing subsystem of clauses 1 or 2, further comprising a board-to-board connector that electronically couples the first PCB and the second PCB.

4. The processing subsystem of any of clauses 1-3, wherein a level difference between the second level and the first level along the first coordinate axis corresponds to a height of the board-to-board connector along the first coordinate axis.

5. The processing subsystem of any of clauses 1-4, wherein the board-to-board connector is disposed between the first PCB and the second PCB along the first coordinate axis.

6. The processing subsystem of any of clauses 1-5, wherein a first component is mounted on the backside of the second PCB, the first component satisfies a height limit specification, and the height limit specification is based on the first level on the first coordinate axis.

7. The processing subsystem of any of clauses 1-6, wherein a specification height of the first component is measured based on the first level on the first coordinate axis for determining whether the height limit specification is met, an actual height of the first component is measured based on the second level on the first coordinate axis, and the actual height of the first component is greater than the specification height of the first component.

8. The processing subsystem of any of clauses 1-7, wherein the first component comprises a power component.

9. The processing subsystem of any of clauses 1-8, further comprising at least one fan that is coupled to the second PCB.

10. The processing subsystem of any of clauses 1-9, wherein the at least one fan is an axial or radial fan.

11. The processing subsystem of any of clauses 1-10, further comprising at least one heat sink coupled to the second PCB, wherein the at least one heat sink includes a plurality of fins.

12. The processing subsystem of any of clauses 1-11, wherein the processing subsystem comprises a peripheral component interconnect express (PCIe) card, and the edge connector is adaptable to be coupled to a PCIe slot of a motherboard.

13. The processing subsystem of any of clauses 1-12, wherein the processor comprises a graphics processing unit.

14. The processing subsystem of any of clauses 1-13, wherein the second PCB further includes a first component mounted on a backside of the second PCB that satisfies a PCIe height limit specification, and the PCIe height limit specification is based on the first level on the first coordinate axis.

15. The processing subsystem of any of clauses 1-14, further comprising at least one heat sink coupled to the processor.

16. In some embodiments, a computer system comprises a chassis, a motherboard disposed within the chassis, and a processing subsystem within the chassis that is communicatively coupled to the motherboard and comprises a first printed circuit board (PCB) that includes an edge connector that is oriented perpendicular to a first coordinate axis and is located at a first level on the first coordinate axis, and a second PCB that is perpendicular to the first coordinate axis and located at a second level on the first coordinate axis, wherein the second level is different from the first level, and the second PCB has a topside on which a processor is mounted.

17. The computer system of clause 16, wherein the second PCB has a backside that faces towards the first PCB, and wherein the topside of the second PCB faces away from the first PCB.

18. The computer system of clauses 16 or 17, wherein the processing subsystem further comprises a board-to-board connector that electronically couples the first PCB and the second PCB.

19. The computer system of any of clauses 16-18, wherein a level difference between the second level and the first level along the first coordinate axis corresponds to a height of the board-to-board connector along the first coordinate axis.

20. The computer system of any of clauses 16-19, wherein the board-to-board connector is disposed between the first PCB and the second PCB along the first coordinate axis.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module” or “system.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon. The software constructs and entities (e.g., engines, modules, GUIs, etc.) are, in various embodiments, stored in the memory/memories shown in the relevant system figure(s) and executed by the processor(s) shown in those same system figures.

Any combination of one or more non-transitory computer readable medium or media may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A processing subsystem, comprising:
a first printed circuit board (PCB) that includes an edge connector that is oriented perpendicular to a first coordinate axis and is located at a first level on the first coordinate axis; and
a second PCB that is perpendicular to the first coordinate axis and located at a second level on the first coordinate axis, wherein the second level is different from the first level, and the second PCB has a topside on which a processor is mounted.

2. The processing subsystem of claim 1, wherein the second PCB has a backside that faces towards the first PCB, and wherein the topside of the second PCB faces away from the first PCB.

3. The processing subsystem of claim 1, further comprising a board-to-board connector that electronically couples the first PCB and the second PCB.

4. The processing subsystem of claim 3, wherein a level difference between the second level and the first level along the first coordinate axis corresponds to a height of the board-to-board connector along the first coordinate axis.

5. The processing subsystem of claim 3, wherein the board-to-board connector is disposed between the first PCB and the second PCB along the first coordinate axis.

6. The processing subsystem of claim 1, wherein a first component is mounted on the backside of the second PCB, the first component satisfies a height limit specification, and the height limit specification is based on the first level on the first coordinate axis.

7. The processing subsystem of claim 6, wherein:
a specification height of the first component is measured based on the first level on the first coordinate axis for determining whether the height limit specification is met;
an actual height of the first component is measured based on the second level on the first coordinate axis, and
the actual height of the first component is greater than the specification height of the first component.

8. The processing subsystem of claim 6, wherein the first component comprises a power component.

9. The processing subsystem of claim 1, further comprising at least one fan that is coupled to the second PCB.

10. The processing subsystem of claim 9, wherein the at least one fan is an axial or radial fan.

11. The processing subsystem of claim 1, further comprising at least one heat sink coupled to the second PCB, wherein the at least one heat sink includes a plurality of fins.

12. The processing subsystem of claim 1, wherein:
the processing subsystem comprises a peripheral component interconnect express (PCIe) card; and
the edge connector is adaptable to be coupled to a PCIe slot of a motherboard.

13. The processing subsystem of claim 12, wherein the processor comprises a graphics processing unit.

14. The processing subsystem of claim 12, wherein:
the second PCB further includes a first component mounted on a backside of the second PCB that satisfies a PCIe height limit specification; and
the PCIe height limit specification is based on the first level on the first coordinate axis.

15. The processing subsystem of claim 1, further comprising at least one heat sink coupled to the processor.

16. A computer system, comprising:
a chassis;
a motherboard disposed within the chassis; and
a processing subsystem within the chassis that is communicatively coupled to the motherboard and comprises:
a first printed circuit board (PCB) that includes an edge connector that is oriented perpendicular to a first coordinate axis and is located at a first level on the first coordinate axis; and
a second PCB that is perpendicular to the first coordinate axis and located at a second level on the first coordinate axis, wherein the second level is different from the first level, and the second PCB has a topside on which a processor is mounted.

17. The computer system of claim 16, wherein the second PCB has a backside that faces towards the first PCB, and wherein the topside of the second PCB faces away from the first PCB.

18. The computer system of claim 16, wherein the processing subsystem further comprises a board-to-board connector that electronically couples the first PCB and the second PCB.

19. The computer system of claim 18, wherein a level difference between the second level and the first level along the first coordinate axis corresponds to a height of the board-to-board connector along the first coordinate axis.

20. The computer system of claim 18, wherein the board-to-board connector is disposed between the first PCB and the second PCB along the first coordinate axis.
